(19) United States
(12) Patent Application Publication
(10) Pub. No.: US 2025/0183856 A1
(43) Pub. Date: Jun. 5, 2025

(54) OUTPUT LOAD AWARE COMPENSATION SCHEME FOR MULTI-STAGE AMPLIFIER

(71) Applicant: MEDIATEK INC., Hsinchu City (TW)

(72) Inventors: You-Shin Chen, Hsinchu City (TW); Sung-Han Wen, Hsinchu City (TW); Ya-Chi Chen, Hsinchu City (TW)

(73) Assignee: MEDIATEK INC., Hsinchu City (TW)

(21) Appl. No.: 18/961,395

(22) Filed: Nov. 26, 2024

Related U.S. Application Data
(60) Provisional application No. 63/604,244, filed on Nov. 30, 2023.

(51) Int. Cl. H03F 1/34; H03F 3/68

(52) U.S. Cl. CPC H03F 1/342; H03F 3/68; H03F 2200/171

(57) ABSTRACT

The present invention provides a multi-stage amplifier including at least one inter-stage amplifier, an output amplifier, a high-pass filter and a feedback amplifier is disclosed. The at least one inter-stage amplifier is configured to amplify an input signal to generate a signal. The output amplifier is configured to receive the signal to generate an output signal. The high-pass filter is configured to filter the signal and the output signal to generate a filtered signal and a filtered output signal, respectively. The feedback amplifier is configured to receive the filtered signal and the filtered output signal to generate a feedback signal to an input terminal of one of the at least one inter-stage amplifier and the output amplifier.

### CROSS REFERENCE TO RELATED APPLICATIONS

This application claims the benefit of U.S. Provisional Application No. 63/604,244, filed on Nov. 30, 2023. The content of the application is incorporated herein by reference.

### BACKGROUND

In an electronic device used to output audio signals, a multi-stage amplifier is typically set up within an audio processing circuit to transmit the audio signal to external headphones. However, the impedance of headphones can experience significant variations, especially when a user suddenly removes the headphones from the electronic device. For example, the output impedance of the multi-stage amplifier may suddenly increase from 16 or 32 ohms to 1 Giga-ohm. This impedance change can greatly reduce the frequency of the output pole of the multi-stage amplifier, affecting its stability.

### SUMMARY

Therefore, one objective of the present invention is to propose a multi-stage amplifier that maintains high stability even when there are significant changes in output impedance, to solve the above-mentioned problems.

According to one embodiment of the present invention, a multi-stage amplifier comprising at least one inter-stage amplifier, an output amplifier, a high-pass filter and a feedback amplifier is disclosed. The at least one inter-stage amplifier is configured to amplify an input signal to generate a signal. The output amplifier is configured to receive the signal to generate an output signal. The high-pass filter is configured to filter the signal and the output signal to generate a filtered signal and a filtered output signal, respectively. The feedback amplifier is configured to receive the filtered signal and the filtered output signal to generate a feedback signal to an input terminal of one of the at least one inter-stage amplifier and the output amplifier.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a multi-stage amplifier according to one embodiment of the present invention.

FIG. 2 is a diagram showing the generation of the output signal of the multi-stage amplifier of FIG. 1 according to one embodiment of the present invention.

FIG. 3 is a diagram illustrating the high-pass filter and the feedback amplifier according to one embodiment of the present invention.

FIG. 4 is a diagram illustrating the high-pass filter and the feedback amplifier according to one embodiment of the present invention.

FIG. 5 is a diagram illustrating the high-pass filter and the feedback amplifier according to one embodiment of the present invention.

FIG. 6 is a multi-stage amplifier according to one embodiment of the present invention.

FIG. 7 is a diagram showing the generation of the output signal of the multi-stage amplifier of FIG. 6 according to one embodiment of the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. The terms “couple” and “couples” are intended to mean either an indirect or a direct electrical connection. Thus, if a first device couples to a second device, that connection may be through a direct electrical connection, or through an indirect electrical connection via other devices and connections.

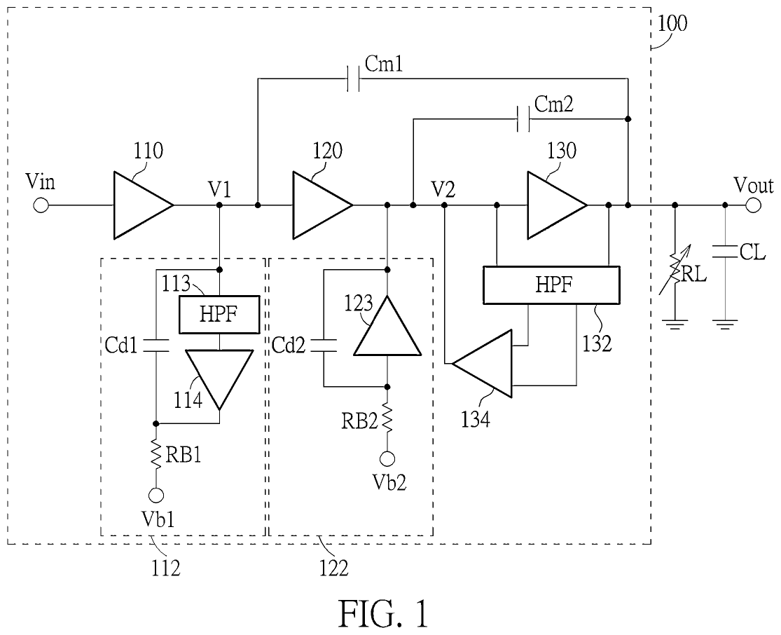

FIG. 1 is a multi-stage amplifier 100 according to one embodiment of the present invention. As shown in FIG. 1, the multi-stage amplifier 100 is configured to receive an input signal Vin to generate an output signal Vout to an external device. In this embodiment, the input signal Vin is an input audio signal, the output signal Vout is an output audio signal, and the multiple-stage amplifier 100 is configured to generate the output audio signal to an external speaker or a pair of headphones, wherein an output load RL and a output capacitor CL represent the impedance and capacitance of the external speaker or the pair of headphones.

As shown in FIG. 1, the multi-stage amplifier 100 comprises three amplifier stages (not a limitation of the present invention). The first amplifier stage is configured to amplify the input signal Vin to generate a first signal V1, and the first amplifier stage comprises an amplifier 110 and a damping circuit 112. The damping circuit 112 comprises a high-pass filter (HPF) 113, a damping amplifier 114, a capacitor Cd1 and a resistor RB1, wherein the high-pass filter 113 is coupled to an output terminal of the amplifier 110 to filter the first signal V1, the damping amplifier 114 is configured to amplify a filtered first signal outputted by the high-pass filter 113, the capacitor Cd1 is coupled between the input terminal of the high-pass filter 113 and the output terminal of the damping amplifier 114, and the resistor RB1 is coupled between a bias voltage Vb1 and the output terminal of the damping amplifier 114.

The second amplifier stage is configured to amplify the first signal V1 to generate a second signal V2, and the second amplifier stage comprises an amplifier 120 and a damping circuit 122. The damping circuit 122 comprises a damping amplifier 123, a capacitor Cd2 and a resistor RB2, wherein an output terminal of the damping amplifier 123 is coupled to the output terminal of the amplifier 120, the capacitor Cd2 is coupled between the input terminal and the output terminal of the damping amplifier 123, and the resistor RB2 is coupled between a bias voltage Vb2 and the input terminal of the damping amplifier 123.

The third amplifier stage (output stage) is configured to receive the second signal V2 to generate the output signal Vout, and the third amplifier stage comprises an amplifier 130, a high-pass filter 132 and a feedback amplifier 134. The high-pass filter 132 is configured to filter the second signal V2 and the output signal Vout to generate a filtered second signal and a filtered output signal, respectively. The feedback amplifier 134 is implemented by using a differential amplifier to receive the filtered second signal and the filtered output signal to generate a feedback signal to the input terminal of the amplifier 130, to compensate the second signal V2. In addition, the multi-stage amplifier 100 comprises two feedback capacitors Cm1 and Cm2, wherein the feedback capacitor Cm1 is coupled between the input terminal of the amplifier 120 and the output terminal of the amplifier 130, and the feedback capacitor Cm2 is coupled between the input terminal and the output terminal of the amplifier 130.

In this embodiment, the feedback amplifier 134 with the high-pass filter 132 provides a negative feedback. That is, the phase provided by the amplifier 130 and the phase provided by the feedback amplifier 134 with the high-pass filter 132 are opposite.

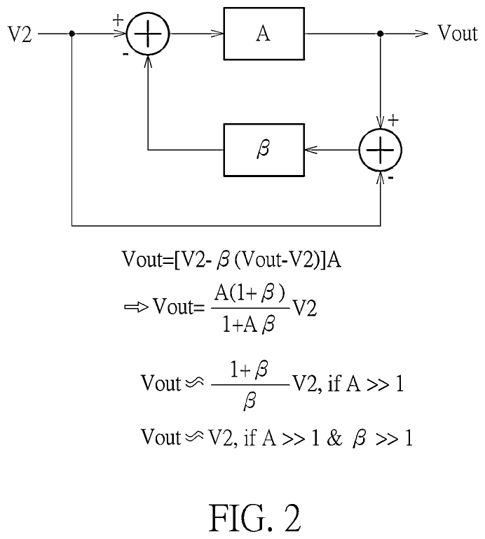

As described in the background of the present invention, an output load RL can be either 16 ohms or 32 ohms when earphones or a speaker are connected to the electronic device featuring the multi-stage amplifier 100. However, when the headphones or speaker are suddenly removed, the output load RL may suddenly increase to 1 Giga-ohm. This sudden change can significantly reduce the output pole of the multi-stage amplifier 100, and its stability may be worsened. To solve this problem, the high-pass filter 132 and the feedback amplifier 134 are designed in the third amplifier stage (output stage). Specifically, referring to FIG. 1 and FIG. 2 together, FIG. 2 is a diagram showing the generation of the output signal Vout according to one embodiment of the present invention. The output signal Vout can be obtained as follows:

$$Vout = [ V 2 - β * ( Vout - V 2 ) ] * A ; \qquad ( 1 )$$

wherein the symbol “A” is “Gm*RL”, the symbol “B” is a feedback gain equal to “Gfb/Gd2”, “Gm” is a transconductance of the amplifier 130, “Gfb” is the gain of the feedback amplifier 134, and “Gd2” is the gain of the damping amplifier 123. When the output load RL increases significantly, the value of A will be much greater than “1”, resulting in the output signal Vout approaching [(1+β)/β]*V2. In this embodiment, since the gain of the feedback amplifier 134 is greater than the gain of the damping amplifier 123, the value of B is much greater than “1”. Consequently, the output signal Vout is close to the second signal V2.

As in the embodiments shown in FIG. 1 and FIG. 2, the output signal Vout is independent of “A” and “β”, so the third amplifier stage functions as an all-pass filter, making the gain response of the third amplifier stage load-independent. In addition, because the loop response variation of the third amplifier stage (i.e., Vout/V2) with respect to changes in output load RL is minimized, the stability of multi-stage amplifier 100 remains unaffected even when the output load RL is significantly increased.

In addition, by designing the high-pass filter 132 in the third amplifier stage, the gain of the signal components in the audio band (20 Hz-20 kHz) will not be affected, and only the high-frequency components are processed under the load-independent unity gain.

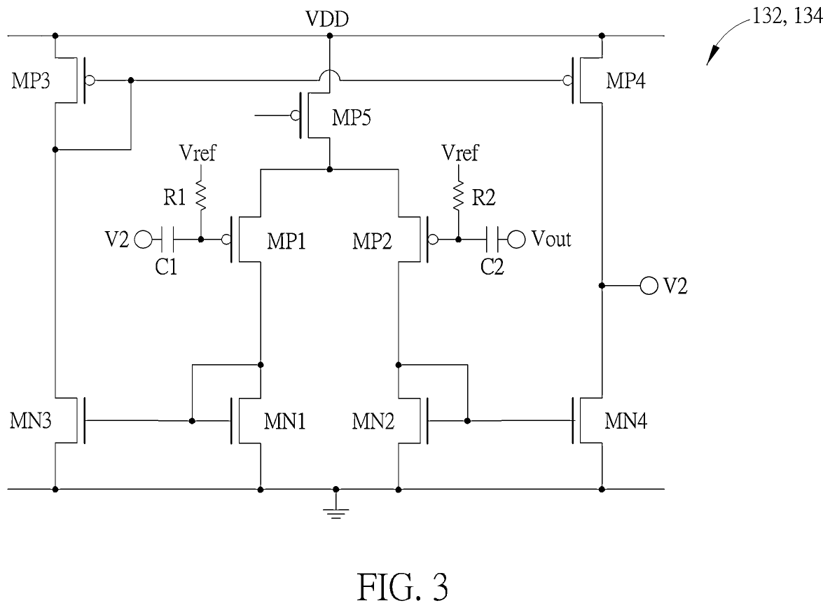

FIG. 3 is a diagram illustrating the high-pass filter 132 and the feedback amplifier 134 according to one embodiment of the present invention. As shown in FIG. 3, the feedback amplifier 134 comprises P-type transistors MP1-MP5 and N-type transistors MN1-MN4 coupled between a supply voltage VDD and a ground voltage. The high-pass filter 132 comprises capacitors C1, C2, the resistors R1 and R2, wherein the capacitor C1 is coupled between the second signal V2 and a gate electrode of the P-type transistor MP1, the resistor R1 is coupled between a reference voltage Vref and the gate electrode of the P-type transistor MP1, the capacitor C2 is coupled between the output signal Vout and a gate electrode of the P-type transistor MP2, and the resistor R2 is coupled between the reference voltage Vref and the gate electrode of the P-type transistor MP2. In this embodiment, the capacitor C1 and the resistor R1 serve as a first high-pass filter to filter the second signal V2 to generate the filtered second signal to the P-type transistor MP1, the capacitor C2 and the resistor R2 serve as a second high-pass filter to filter the output signal Vout to generate the filtered output signal to the P-type transistor MP2, and the feedback amplifier 134 receives the filtered second signal and the filtered output signal to generate a feedback signal at the drain electrode of the P-type transistor MP4, wherein the feedback signal is transmitted to the input terminal of the amplifier 130 to compensate the second signal V2.

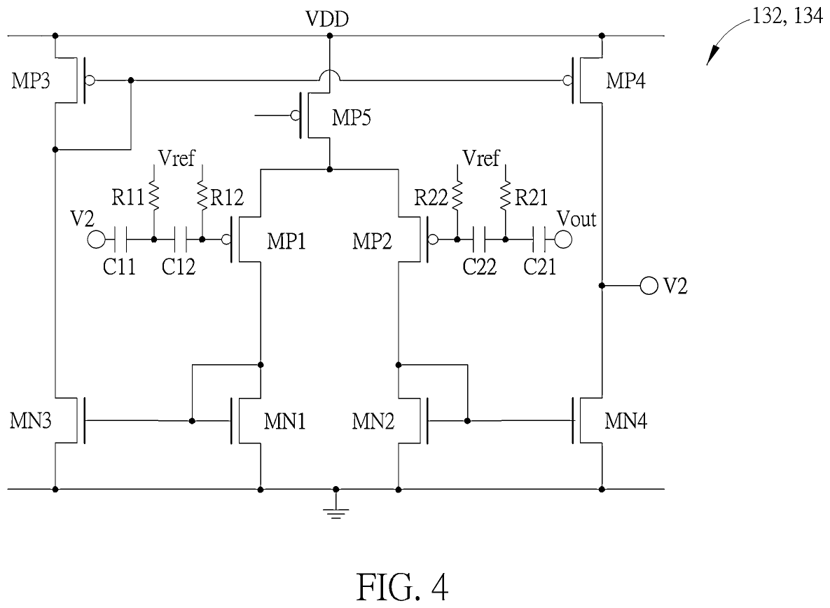

FIG. 4 is a diagram illustrating the high-pass filter 132 and the feedback amplifier 134 according to one embodiment of the present invention. As shown in FIG. 4, the feedback amplifier 134 comprises P-type transistors MP1-MP5 and N-type transistors MN1-MN4 coupled between a supply voltage VDD and a ground voltage. The high-pass filter 132 comprises capacitors C11, C12, C21, C22, the resistors R11, R12, R21 and R22, wherein the capacitor C11 and C12 are coupled between the second signal V2 and a gate electrode of the P-type transistor MP1, the resistor R11 is coupled between a reference voltage Vref and a node coupled between the capacitors C11 and C12, and the resistor R12 is coupled between the reference voltage and the gate electrode of the P-type transistor MP1, the capacitor C21 and C22 are coupled between the output signal Vout and a gate electrode of the P-type transistor MP2, the resistor R21 is coupled between the reference voltage Vref and a node coupled between the capacitors C21 and C22, and the resistor R22 is coupled between the reference voltage and the gate electrode of the P-type transistor MP2. In this embodiment, the capacitors C11, C12, the resistors R11 and R12 serve as a first high-pass filter to filter the second signal V2 to generate the filtered second signal to the P-type transistor MP1, the capacitors C21, C22, the resistors R21 and R22 serve as a second high-pass filter to filter the output signal Vout to generate the filtered output signal to the P-type transistor MP2, and the feedback amplifier 134 receives the filtered second signal and the filtered output signal to generate a feedback signal at the drain electrode of the P-type transistor MP4, wherein the feedback signal is transmitted to the input terminal of the amplifier 130 to compensate the second signal V2.

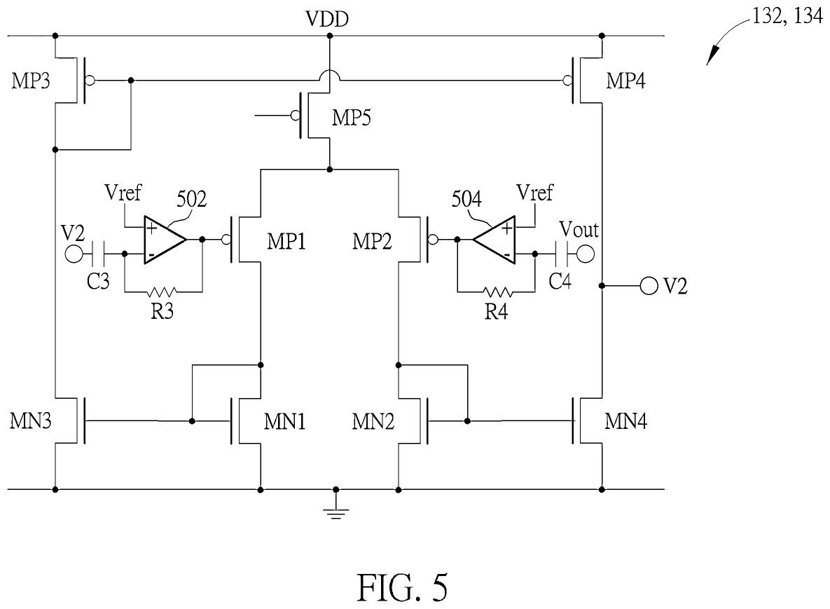

FIG. 5 is a diagram illustrating the high-pass filter 132 and the feedback amplifier 134 according to one embodiment of the present invention. As shown in FIG. 5, the feedback amplifier 134 comprises P-type transistors MP1-MP5 and N-type transistors MN1-MN4 coupled between a supply voltage VDD and a ground voltage. The high-pass filter 132 comprises capacitors C3, C4, resistors R3, R4, and operational amplifiers 502 and 204, wherein a negative input terminal of the operational amplifier 502 is coupled to the second signal V2 via the capacitor C3, a positive input terminal of the operational amplifier 502 is coupled to a reference voltage Vref, an output terminal of the operational amplifier 502 is coupled to a gate electrode of the P-type transistor MP1, and a resistor R3 is coupled between an output terminal and the negative input terminal of the operational amplifier 502; and a negative input terminal of the operational amplifier 504 is coupled to the output signal Vout via the capacitor C4, a positive input terminal of the operational amplifier 504 is coupled to a reference voltage Vref, an output terminal of the operational amplifier 504 is coupled to a gate electrode of the P-type transistor MP2, and a resistor R4 is coupled between an output terminal and the negative input terminal of the operational amplifier 504. In this embodiment, the capacitor C3, the resistor R3 and the operational amplifier 502 serve as a first high-pass filter to filter the second signal V2 to generate the filtered second signal to the P-type transistor MP1, the capacitor C4, the resistor R4 and the operational amplifier 504 serve as a second high-pass filter to filter the output signal Vout to generate the filtered output signal to the P-type transistor MP2, and the feedback amplifier 134 receives the filtered second signal and the filtered output signal to generate a feedback signal at the drain electrode of the P-type transistor MP4, wherein the feedback signal is transmitted to the input terminal of the amplifier 130 to compensate the second signal V2.

It is noted that the embodiments shown in FIG. 3-FIG. 5 are for illustrative, not a limitation of the present invention. In other embodiments, the feedback amplifier 134 can be implemented by any type of differential amplifier, and the high-pass filter 132 can be implemented by any type of high-pass filter such as first-order high-pass filter, second-order high-pass filter, higher-order high-pass filter, passive high-pass filter or active high-pass filter.

In the above embodiments shown in FIG. 1 and FIG. 2, the multi-stage amplifier 100 are three-stage amplifier, however, this feature is not a limitation of the present invention. In other embodiments, the multiple stage amplifier 100 can be implemented to have two or more amplifiers connected in cascaded. As long as the multiple stage amplifier 100 has at least one inter-stage amplifier (e.g., amplifiers 110 and 120) and an output amplifier (e.g., amplifier 130), and the high-pass filter 132 and the feedback amplifier 134 work with the output amplifier, the other circuits within the multiple stage amplifier 100 can have different designs.

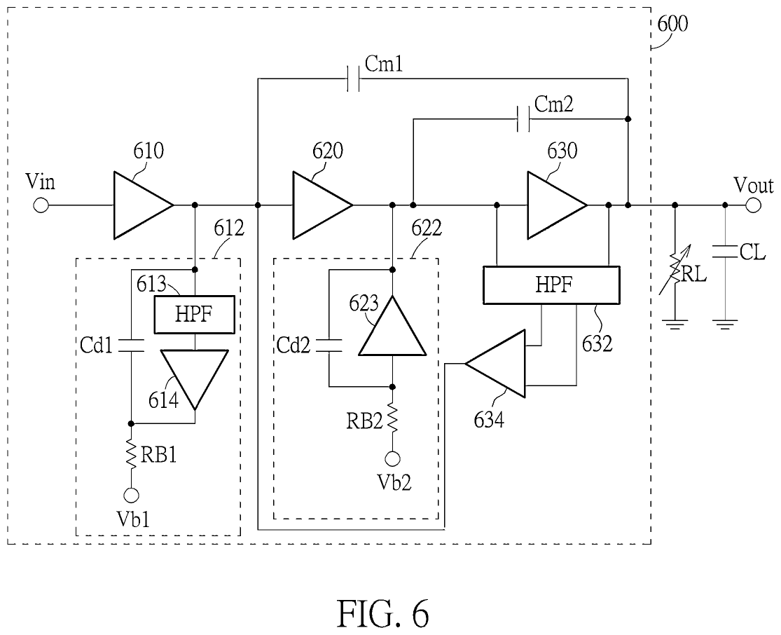

In the above embodiments shown in FIG. 1 and FIG. 2, the feedback signal generated by the feedback amplifier 134 are inputted into the input terminal of the amplifier 130, however, this feature is not a limitation of the present invention. In other embodiments, the feedback signal generated by the feedback amplifier 134 may be inputted into an input terminal of any inter-stage amplifier. FIG. 6 is a multi-stage amplifier 600 according to one embodiment of the present invention. As shown in FIG. 6, the multi-stage amplifier 600 is configured to receive an input signal Vin to generate an output signal Vout to an external device. In this embodiment, the input signal Vin is an input audio signal, the output signal Vout is an output audio signal, and the multiple-stage amplifier 600 is configured to generate the output audio signal to an external speaker or a pair of headphones, wherein an output load RL and a output capacitor CL represent the impedance and capacitance of the external speaker or the pair of headphones.

As shown in FIG. 6, the multi-stage amplifier 600 comprises three amplifier stages (not a limitation of the present invention). The first amplifier stage is configured to amplify the input signal Vin to generate a first signal V1, and the first amplifier stage comprises an amplifier 610 and a damping circuit 612. The damping circuit 612 comprises a high-pass filter 613, a damping amplifier 614, a capacitor Cd1 and a resistor RB1, wherein the high-pass filter 613 is coupled to an output terminal of the amplifier 610 to filter the first signal V1, the damping amplifier 614 is configured to amplify a filtered first signal outputted by the high-pass filter 613, the capacitor Cd1 is coupled between the input terminal of the high-pass filter 613 and the output terminal of the damping amplifier 614, and the resistor RB1 is coupled between a bias voltage Vb1 and the output terminal of the damping amplifier 614.

The second amplifier stage is configured to amplify the first signal V1 to generate a second signal V2, and the second amplifier stage comprises an amplifier 620 and a damping circuit 622. The damping circuit 622 comprises a damping amplifier 623, a capacitor Cd2 and a resistor RB2, wherein an output terminal of the damping amplifier 623 is coupled to the output terminal of the amplifier 620, the capacitor Cd2 is coupled between the input terminal and the output terminal of the damping amplifier 623, and the resistor RB2 is coupled between a bias voltage Vb2 and the input terminal of the damping amplifier 623.

The third amplifier stage (output stage) is configured to receive second signal V2 to generate the output signal Vout, and the third amplifier stage comprises an amplifier 630, a high-pass filter 632 and a feedback f amplifier 634. The high-pass filter 632 is configured to filter the second signal V2 and the output signal Vout to generate a filtered second signal and a filtered output signal, respectively. The feedback amplifier 634 is implemented by using a differential amplifier to receive the filtered second signal and the filtered output signal to generate a feedback signal to the input terminal of the amplifier 620, to compensate the first signal V1. In addition, the multi-stage amplifier 600 comprises two feedback capacitors Cm1 and Cm2, wherein the feedback capacitor Cm1 is coupled between the input terminal of the amplifier 620 and the output terminal of the amplifier 630, and the feedback capacitor Cm2 is coupled between the input terminal and the output terminal of the amplifier 630.

In this embodiment, the feedback amplifier 634 with the high-pass filter 632 provides a negative feedback.

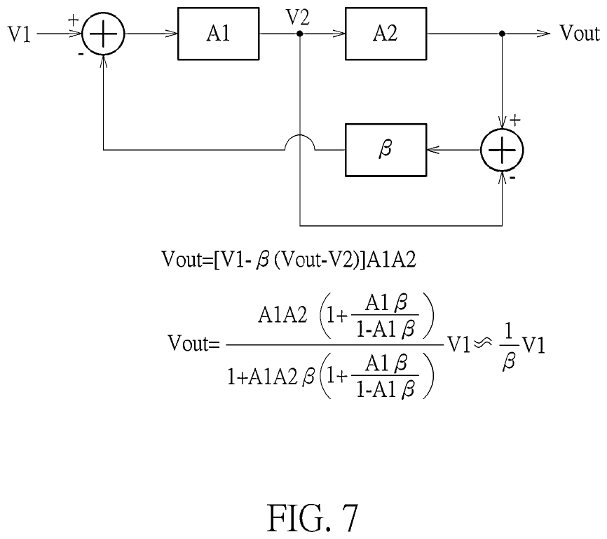

As described in the background of the present invention, the sudden change of the output load RL can significantly reduce the output pole of the multi-stage amplifier 600, and its stability may be worsened. To solve this problem, the high-pass filter 632 and the feedback amplifier 634 are designed in the third amplifier stage (output stage). Specifically, referring to FIG. 6 and FIG. 7 together, FIG. 7 is a diagram showing the generation of the output signal Vout according to one embodiment of the present invention. The output signal Vout can be obtained as follows:

$$Vout = [ V 1 - β * ( Vout - V 2 ) ] * A 1 * A 2 ; \qquad ( 2 )$$

wherein the symbol “A1” represents the gain of the amplifier 620, the symbol “A2” is “Gm*RL”, the symbol “B” is a feedback gain equal to “Gfb/Gd2”, “Gm” is a transconductance of the amplifier 630, “Gfb” is the gain of the feedback amplifier 634, and “Gd2” is the gain of the damping amplifier 623. When the output load RL increases significantly, the value of A will be much greater than “1”, resulting in the output signal Vout approaching (1/β)*V2.

As in the embodiments shown in FIG. 6 and FIG. 7, the output signal Vout is independent of “A”, so the gain response of the third amplifier stage is load-independent. In addition, because the loop response variation of the third amplifier stage (i.e., Vout/V2) with respect to changes in output load RL is minimized, the stability of multi-stage amplifier 600 remains unaffected even when the output load RL is significantly increased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A multi-stage amplifier, comprising:
at least one inter-stage amplifier, configured to amplify an input signal to generate a signal;
an output amplifier, configured to receive the signal to generate an output signal;
a high-pass filter, configured to filter the signal and the output signal to generate a filtered signal and a filtered output signal, respectively; and
a feedback amplifier, configured to receive the filtered signal and the filtered output signal to generate a feedback signal to an input terminal of one of the at least one inter-stage amplifier and the output amplifier.

2. The multi-stage amplifier of claim 1, wherein the feedback amplifier receives the filtered signal and the filtered output signal to generate the feedback signal to the input terminal of the output amplifier, to compensate the signal.

3. The multi-stage amplifier of claim 2, wherein the feedback amplifier with the high-pass filter provides a negative feedback for the output amplifier.

4. The multi-stage amplifier of claim 1, wherein the at least one inter-stage amplifier comprises a first amplifier and a second amplifier, the first amplifier is configured to generate a first signal according to the input signal, the second amplifier is configured to amplify the first signal to generate the signal; and the feedback amplifier receives the filtered signal and the filtered output signal to generate the feedback signal to the input terminal of the second amplifier, to compensate the first signal.

5. The multi-stage amplifier of claim 4, wherein the feedback amplifier with the high-pass filter provides a negative feedback for the second amplifier.

6. The multi-stage amplifier of claim 1, wherein the high-pass filter comprises a first high-pass filter and a second high-pass filter, the first high-pass filter is configured to filter the signal to generate the filtered signal, and the second high-pass filter is configured to filter the output signal to generate the filtered output signal.

7. The multi-stage amplifier of claim 1, wherein the feedback amplifier is a differential amplifier.

8. The multi-stage amplifier of claim 1, wherein the output amplifier works as an all-pass filter.

9. The multi-stage amplifier of claim 1, wherein the output amplifier with the high-pass filter and the feedback amplifier work as a unity-gain amplifier.

10. The multi-stage amplifier of claim 1, where the input signal is an audio input signal, and the multi-stage amplifier generates the output signal to an external speaker or headphones.
